(19) United States
(12) Patent Application Publication
(10) Pub. No.: US 2025/0081787 A1
(43) Pub. Date: Mar. 6, 2025

(54) DISPLAY PANEL AND METHOD FOR PREPARING THE SAME, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Dongfang YANG, Beijing (CN); Kening ZHENG, Beijing (CN); Dengyu WANG, Beijing (CN); Yamin YANG, Beijing (CN); Xueguang HAO, Beijing (CN); Jingquan WANG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/285,879

(22) PCT Filed: Apr. 29, 2022
(86) PCT No.: PCT/CN2022/090235

§ 371 Date: Oct. 6, 2023

(51) Int. Cl. H10K 59/35; H10K 50/852; H10K 59/12; H10K 71/16; H10K 102/00

(52) U.S. Cl. CPC H10K 59/353; H10K 50/852; H10K 59/1201; H10K 71/164; H10K 2102/351

(57) ABSTRACT

The present disclosure provides a display panel, a method for preparing the same, and a display device. The display panel includes a substrate and a light-emitting functional layer. The substrate includes a first display area and a second display area at least partially surrounding the first display area, the first display area being configured for image display and light transmission, the second display area being configured for image display. The light-emitting functional layer is disposed on a side of the substrate, and includes an organic electroluminescent layer. Each of the first display area and the second display area includes a plurality of sub-pixels emitting light of different colors, and organic electroluminescent layers of respective sub-pixels of the plurality of sub-pixels in the first display area emit light of a same color.

### CROSS-REFERENCE TO RELATED APPLICATION

The present disclosure is a national phase entry under 35 U.S.C. § 371 of International Application No. PCT/CN2022/090235, filed on Apr. 29, 2022, the entire contents of which are hereby incorporated by reference in its entirety.

### TECHNICAL FIELD

The present disclosure relates to the field of display technology, and in particular, to a display panel, a method for preparing the same, and a display device.

### BACKGROUND

With the development of display technology, full-screen or narrow-bezel products have gradually become the trend of display products with their large screen-to-body ratio and ultra-narrow bezel. Products such as smart terminals usually require hardware such as front-facing cameras, fingerprint sensors or light sensors, and in order to increase the screen-to-body ratio, full-screen or narrow-bezel products usually use a Full Display with Camera (FDC) technology or under-screen fingerprint technology to place the camera and other sensors in an Under Display Camera (UDC) area of the display substrate. The UDC area not only has a certain transmittance rate, but also has a display function. In related art, the FDC area has the problem of low gray-scale color cast on the white screen.

It should be noted that the information disclosed above in the background section is only used to enhance the understanding of the background of the present disclosure, and therefore may include information that does not constitute the prior art known to those of ordinary skill in the art.

### SUMMARY

The purpose of the present disclosure is to provide a display panel, a method for preparing the same, and a display device, in order to overcome the deficiencies of the above prior art.

According to a first aspect of the present disclosure, there is provided a display panel, including: a substrate including a first display area and a second display area at least partially surrounding the first display area, the first display area being configured for image display and light transmission, the second display area being configured for image display; and a light-emitting functional layer on a side of the substrate, including an organic electroluminescent layer; wherein each of the first display area and the second display area includes a plurality of sub-pixels emitting light of different colors, and organic electroluminescent layers of respective sub-pixels of the plurality of sub-pixels in the first display area emit light of a sane color.

According to a second aspect of the present disclosure, there is provided a method for preparing a display panel, wherein the method is configured for preparing the display panel of any one of the embodiments of the present disclosure. The method includes: providing a substrate, wherein the substrate includes: a first display area configured for image display and light transmission, and a second display area at least partially surrounding the first display area, configured for image display, each of the first display area and the second display area including a plurality of sub-pixels emitting light of different colors; and forming a light-emitting functional layer on a side of the substrate by using an evaporation process, wherein the light-emitting functional layer includes an organic electroluminescent layer, organic electroluminescent layers of respective sub-pixels of the plurality of sub-pixels in the first display area emitting light of a same color.

According to a third aspect of the present disclosure, there is provided a display device, including the display panel as described in the first aspect.

It should be understood that the above general description and the following detailed description are only exemplary and explanatory, and cannot limit the present disclosure.

### BRIEF DESCRIPTION OF THE DRAWINGS

The drawings herein, which are incorporated in and constitute a part of the specification, illustrate embodiments consistent with the present disclosure, and serve to explain the principles of the present disclosure together with the description. Obviously, the drawings in the following description show only some of embodiments of the present disclosure. For those of ordinary skill in the art, other drawings may be obtained based on these drawings without creative efforts.

FIG. 1 is a schematic diagram of a structure of a display panel according to an embodiment of the present disclosure.

FIG. 2 is a schematic diagram of a structure of pixel units in a first display area and a second display area in a sectional view of FIG. 1 along a direction AA.

FIG. 3 illustrates luminescence spectrum curves of an R sub-pixel according to an embodiment of the present disclosure.

FIG. 4 illustrates luminescence spectrum curves of a G sub-pixel according to an embodiment of the present disclosure.

FIG. 5 illustrates luminescence spectrum curves of a B sub-pixel according to an embodiment of the present disclosure.

FIG. 6 is a schematic diagram of a structure of a first organic layer formed in a preparation process according to an embodiment of the present disclosure.

FIG. 7 is a schematic diagram of a structure of a light-emitting adjustment layer formed in a preparation process according to an embodiment of the present disclosure.

FIG. 8 is a schematic diagram of a structure of a light-emitting layer formed in a preparation process according to an embodiment of the present disclosure.

FIG. 9 is a schematic diagram of a structure of a second organic layer formed in a preparation process according to an embodiment of the present disclosure.

FIG. 10 is a schematic diagram of a structure of a pixel unit formed in a preparation process according to an embodiment of the present disclosure.

### DETAILED DESCRIPTION

Exemplary embodiments will now be described more fully with reference to the accompanying drawings. However, the exemplary embodiments can be implemented in a variety of forms and should not be construed as being limited to the embodiments set forth herein. Rather, these embodiments are provided so that the present disclosure will be comprehensive and complete, and the idea of the exemplary embodiments will fully conveyed to those skilled in the art. The same numerals in the drawings denote the same or similar structures, and thus their detailed descriptions will be omitted. Furthermore, the accompanying drawings are only schematic illustrations of the present disclosure and are not necessarily drawn to scale,

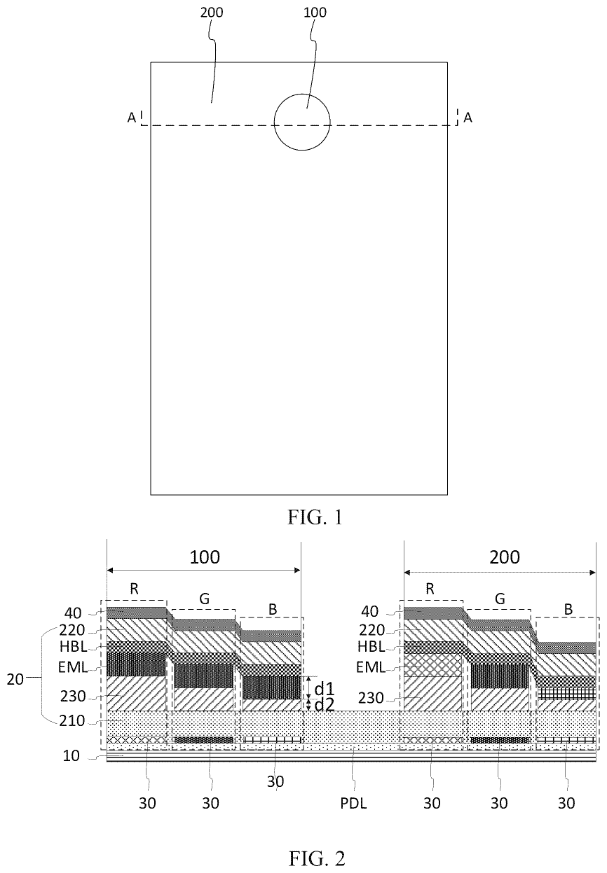

FIG. 1 is a schematic diagram of a structure of a display panel according to an embodiment of the present disclosure. FIG. 2 is a schematic diagram of a structure of pixel units in a first display area and a second display area in a sectional view of FIG. 1 along a direction AA. As shown in FIGS. 1 and 2, in the exemplary embodiment, the display panel may include a substrate 10 and a light-emitting functional layer 20. The substrate 10 may include a first display area 100 and a second display area 200 at least partially surrounding the first display area 100. The first display area 100 is configured for image display and light transmission. The second display area 200 is configured for image display. The light-emitting functional layer 20 is disposed on a side of the substrate 10, and the light-emitting functional layer 20 may include an organic electroluminescent layer EML. Each of the first display area 100 and the second display area 200 includes a plurality of sub-pixels emitting light of different colors, and organic electroluminescent layers EML of respective sub-pixels of the plurality of sub-pixels in the first display area 100 emit light of a same color.

In the display panel provided by the present disclosure, both the first display area 100 and the second display area 200 include sub-pixels emitting light of different colors, and the light emitted from the organic electroluminescent layers EML of the respective sub-pixels in the first display area 100 has the same color. That is, the organic electroluminescent layers EML of the respective sub-pixels in the first display area 100 are formed by the same material, thereby enabling the respective sub-pixels in the first display area 100 to have the same turn-on voltage and solving the problem of color cast of the white screen in low gray scale.

As shown in FIG. 1, in the exemplary embodiment, the first display area 100 may be an FDC area, and the second display area 200 may be a normal display area. The position of the first display area 100 in the second display area 200 may be unlimited. The first display area 100 may be located in the upper or lower portion of the second display area 200 or may be located at an edge position of the second display area 200. In this exemplary embodiment, in a plane parallel to the display substrate, the shape of the first display area 100 may be any one or more of the following: a square, a rectangle, a polygon, a circle, an ellipse, etc. An optical device such as a fingerprint identification device, a camera, or an optical sensor (e.g.-a 3D imaging sensor) may be placed in the first display area 100. When the shape of the first display area 100 is a circle, the diameter of the circle may range from 3 mm to 4 mm; when the shape of the first display area 100 is a rectangle, the side length of the rectangle may range from 3 mm to 4 mm, which is not limited herein by the present disclosure.

The “organic electroluminescent layers EML of respective sub-pixels of the plurality of sub-pixels in the first display area 100 emit light of a same color” means that the organic electroluminescent layers EML of the respective sub-pixels in the first display area 100 are formed by the same light-emitting material. For example, the first display area 100 may include an R sub-pixel emitting red light, a G E sub-pixel emitting green light, and a B sub-pixel emitting blue light. Accordingly, the organic electroluminescent layers EML of the R sub-pixel, the G sub-pixel, and the B sub-pixel in the first display area 100 may be formed by a light-emitting material that emits green light; or the organic electroluminescent layers EML of the R sub-pixel, the G sub-pixel, and the B sub-pixel in the first display area 100 may be formed by a light-emitting material that emits red light; or the organic electroluminescent layers EML of the R sub-pixel, the G sub-pixel, and the B sub-pixel in the first display area 100 may be formed by a light-emitting material that emits blue light. The organic electroluminescent layers EML of the respective sub-pixels of the first display area 100 are formed by the same light-emitting material, so as to enable the respective sub-pixels of the first display area 100 to have the same turn-on voltage, solve the problem of color cast of the white screen in low gray scale, and improve the display picture quality of the first display area 100.

As shown in FIG. 2, in this exemplary embodiment, the organic electroluminescent layers EML of the respective sub-pixels in the first display area 100 are formed of the same material, thereby reducing the number of wires and the spacing of the wires in the first display area 100, i.e., reducing the space occupied by the wires, and thus reducing the size of the first display area 100 as a whole. For example, when an orthographic projection of the first display area on the substrate is a circular, an aperture diameter of the first display area may range from 3 mm to 4 mm.

It should be understood that, in the present exemplary embodiment, the display panel may further include a first electrode layer 30, a pixel definition layer PDL, a second electrode layer 40, and a color film layer (not shown in FIG. 2). The first electrode layer 30 may include a plurality of first electrodes spaced apart, an orthographic projection of each first electrode of the plurality of first electrodes on the substrate is located in a pixel area, and the plurality of first electrodes are connected to pixel circuits. One first electrode of the plurality of first electrodes is connected to one pixel circuit. The pixel definition layer PDL and the first electrode layer 30 are disposed on the same side of the substrate, and the pixel definition laver PDL exposes the respective first electrodes. The pixel definition layer PDL includes a plurality of pixel definition structures. The plurality of pixel definition structures are spaced apart in a direction of arrangement of the pixels, and two adjacent pixel definition structures define a sub-pixel. It should be understood that there is a pixel definition structure (not shown) between two adjacent sub-pixels in FIG. 2. The light-emitting functional layer 20 covers the pixel definition layer PDL and the first electrode layer 30. The second electrode layer covers the light-emitting functional layer 20. The second electrode layer 40 may include a second electrode, the second electrode may be a cathode, and correspondingly, the first electrode may be an anode. Of course, in other embodiments, the second electrode may be an anode and the first electrode is a cathode, which is not limited by the present disclosure.

The color film layer has a plurality of filter portions. One sub-pixel includes one filter portion, and several sub-pixels form a pixel unit. Since the colors of light transmittable by different filter portions may be different, the colors of light emitted by different sub-pixels may be different. The specific structure of the color film layer is not described in detail herein. The same pixel unit includes multiple sub-pixels of different colors. For example, a pixel unit may include three sub-pixels having red, green and blue light-emitting colors, respectively. As a result, the color display can be realized by a plurality of pixel units.

For example, the organic electroluminescent layer EML in the first display area 100 emits green light. After the green light emitted by the organic electroluminescent layer EML of the R sub-pixel is adjusted by the microcavity, the green light can be red-shifted, and then the R sub-pixel can finally emit red light by the filtering effect of the color film layer located in the path of the emitted light. Similarly, the B sub-pixel can emit blue light through microcavity adjustment and filtering.

It should be understood that, in this exemplary embodiment, the second display area 200 may have the same structure as the AA area of an existing display panel, which will not be repeated herein.

In the related art, the FDC area and the normal display area may have the same resolution in order to improve the display quality of the FDC area. On this basis, in order to take into account the transmittance of light, the light-emitting area of the FDC area will be small. However, since the Organic Light Emitting Diode (OLED) is driven by current, in order to achieve the same brightness as the normal display area, the reduced light emitting area will result in a higher current requirement, which in turn leads to a deterioration in the lifetime of the FDC area compared to the normal display area, thus affecting the image quality of the FDC area. The present disclosure, by improving the organic electroluminescent layer EML in the FDC area of the display panel, may address the above issues. The scheme of the present disclosure is further described below in conjunction with the accompanying drawings, and without special description, the first light-emitting material described in the present disclosure emits green light, the second light-emitting material emits red light, and the third light-emitting material emits blue light.

In this exemplary embodiment, the organic electroluminescent layers EML in the first display area 100 may be formed using a light-emitting material with a higher light-emitting efficiency to improve the lifetime of each sub-pixel of the first display area 100. For example, the pixel unit of the first display area 100 includes an R sub-pixel emitting red light, a G sub-pixel emitting green light, and a B sub-pixel emitting blue light, and the organic electroluminescent layers EML in the first display area 100 may be formed using the first light-emitting material. It should be understood that in other exemplary embodiments, the organic electroluminescent layers of respective sub-pixels in the first display area 100 may also emit light of different colors. For example, the organic electroluminescent layer of the R sub-pixel and the organic electroluminescent layer of the B sub-pixel in the first display area 100 may be formed of the second light-emitting material, and the organic electroluminescent layer of the G sub-pixel may be formed of the first light-emitting material; or, the organic electroluminescent layer of the R sub-pixel and the organic electroluminescent layer of the G sub-pixel may be formed of the first light-emitting material, and the organic electroluminescent layer of the B sub-pixel is formed of the second light-emitting material. All of the above solutions may improve the light-emitting efficiency of at least some of the sub-pixels to a certain extent, and thus contribute to improving the lifetime of at least some of the sub-pixels, which fall within the scope of protection of the present disclosure.

The present disclosure only exemplifies the structure and working principle of the first display area 100 by taking the example that the first display area 100 includes three sub-pixels, R, G, and B, and that the organic electroluminescent layers EML of the first display area 100 are formed by the first light-emitting material that emits green light.

In this exemplary embodiment, the light-emitting efficiency of the light-emitting material can be understood as the light-emitting intensity of the light-emitting material when a drive current of a unit intensity is used. The light-emitting efficiency of the first light-emitting material is greater than the light-emitting efficiency of the second light-emitting material, which can be understood as the light-emitting intensity of a first organic electroluminescent material is greater than the light-emitting intensity of a second organic electroluminescent material when the driving current is the same. By using the light-emitting material with high light-emitting efficiency to form the organic electroluminescent layer EML in the first display area 100, the overall light-emitting efficiency of each sub-pixel of the first display area 100 can be improved, so that when the aperture ratio of the first display area 100 is reduced to increase the transmittance of the light of the first display area 100, the drive current for the organic electroluminescent layer EML does not need to be increased, and the lifetime of each sub-pixel in the first display area 100 can be extended. As a result, the lifetime of the first display area 100 can be balanced with the light-emitting efficiency.

As shown in FIG. 2, in this exemplary embodiment, the light-emitting functional layer 20 includes a first organic layer 210, and a second organic layer 220 in addition to the organic electroluminescent layer EML The first organic layer 210 is disposed between the organic electroluminescent layer EML and the substrate, and the second organic layer 220 is disposed on a side of the organic electroluminescent layer EML away from the substrate. The first organic layer 210 may include a hole injection layer HIL and a hole transport layer HTL, and the second organic layer 220 may include an electron transport layer ETL and an electron injection layer EIL. The specific structures of the hole injection layer HIL, the hole transport layer HTL, the electron transport layer ETL, and the electron injection layer EIL will not be described in detail herein. Adjacent light-emitting functional layers may share one or more of the hole injection layer HIL, the hole transport layer HTL, the electron transport layer ETL, and the electron injection layer EIL.

As shown in FIG. 2, in this exemplary embodiment, the light-emitting functional layer 20 may further include a hole blocking layer HBL and a light-emitting adjustment layer 230. The hole blocking layer HBL is disposed between the second organic layer 220 and the organic electroluminescent layer EML of the corresponding sub-pixel, and the specific structure of the hole blocking layer HBL will not be described herein in detail. Adjacent light-emitting functional layers 20 may share the hole blocking layer HBL. The light-emitting adjustment layer 230 is disposed between the hole transport layer HTL and the organic electroluminescent layer EML of the corresponding sub-pixel, and the light-emitting adjustment layer 230 corresponds to each sub-pixel, and can be used to adjust the length of the microcavity of each sub-pixel, and thus to adjust the peak wavelengths of the spectrum of the light emitted from each sub-pixel. The light-emitting adjustment layer 230 of the R sub-pixel may be formed by the second light-emitting material that emits red light, the light-emitting adjustment layer 230 of the G sub-pixel may be formed by the first light-emitting material that emits green light, and the light-emitting adjustment layer 230 of the B sub-pixel may be formed by the third light-emitting material that emits blue light. The thickness of the light-emitting adjustment layer 230 of the R sub-pixel may be greater than the thickness of the light-emitting adjustment layer 230 of the G sub-pixel, and the thickness of the light-emitting adjustment layer 230 of the G sub-pixel is greater than the thickness of the light-emitting adjustment layer 230 of the B sub-pixel, i.e. the thickness of the light-emitting adjustment layer 230 of the B sub-pixel is minimum, and the thickness of the light-emitting adjustment layer 230 of the R sub-pixel is maximum which may control the length of the microcavity of the B sub-pixel to be minimized to cause a blue shift in the light-emitting spectrum of the organic electroluminescent layer EML, and the length of the microcavity of the R sub-pixel to be maximized to cause a red shift in the light-emitting spectrum of the organic electroluminescent layer EML.

For example, the thickness of the light-emitting adjustment layer 230 of the R sub-pixel may range from 750 Å to 800 Å, the thickness of the light-emitting adjustment layer 230 of the G sub-pixel may range from 300 Å to 350 Å, and the thickness of the light-emitting adjustment layer 230 of the B sub-pixel may range from 50 Å to 100 Å.

Furthermore, as shown in FIG. 2, in the present exemplary embodiment, the length of the microcavity of the R sub-pixel in the first display area 100 may be larger than the length of the microcavity of the R sub-pixel in the second display area 200; the length of the microcavity of the G sub-pixel in the first display area 100 may be the same as the length of the microcavity of the B sub-pixel in the second display area 200; and the length of the microcavity of the B sub-pixel in the first display area 100 may be larger than the length of the microcavity of the B sub-pixel in the second display area 200. For example, the microcavity length of the R sub-pixel in the first display area 100 may be greater than or equal to 2700 nm and less than or equal to 2900 nm (e.g., it may be 2700 nm, 2800 nm 2900 nm etc.); the length of the microcavity of the G sub-pixel may be greater than or equal to 2150 nm and less than or equal to 2350 nm (e.g., it may be 2150 nm, 2250 nm, 2350 nm, etc.); and the length of the microcavity of the B sub-pixel may be greater than or equal to 1900 nm and less than or equal to 2100 nm (e.g., it may be 900 nm, 2000 nm 2100 nm, etc.).

As shown in FIG. 2, in this exemplary embodiment, the thickness of the organic electroluminescent layer EML of each sub-pixel in the first display area 100 may be the same or different. When the thickness of the organic electroluminescent layer EML of each sub-pixel is the same, the preparation process can be simplified and the preparation efficiency can be unproved. For example, the thickness of the organic electroluminescent layer EML of each sub-pixel may range from 350 Å to 400 Å, and in this case, the organic electroluminescent layer can be formed by evaporation in the corresponding sub-pixel without the Fine Metal Mask (FMM) masking process. When the thickness of the organic electroluminescent layer EML of each sub-pixel is different, the FMM masking process can be used to form the organic electroluminescent layers of different thicknesses in the respective sub-pixels. For example, the thickness of the organic electroluminescent layer EML of the R sub-pixel may range from 450 Å to 500 Å, the thickness of the organic electroluminescent layer EML of the G sub-pixel may range from 350 Å to 400 Å, and the thickness of the organic electroluminescent layer EML of the B sub-pixel may range from 150 Å to 200 Å.

As shown in FIG. 2, in this exemplary embodiment, in the first display area 100, the thickness of the organic electroluminescent layer EML may be in a certain proportion to the thickness of the light-emitting adjustment layer 230. For example, the thickness of the organic electroluminescent layer EML of each sub-pixel in the first display area 100 is the same, i.e., being d1, and the thickness of the light-emitting adjustment layer 230 of the B sub-pixel in the first display area 100 is d2, and d1/d2 may be greater than or equal to 3 and less than or equal to 9. For example, d1/d2 may be 3, 0.35, 4, 0.45, 5, 0,55, 6, 0.65, 7, 0.75, 8, 0.85, 9, and the like. For example, the thickness of the light-emitting adjustment layer 230 of the B sub-pixel in the first display area 100 may range from 150 Å to 200 Å, and the thickness of the organic electroluminescent layer EML in the first display area 100 may range from 350 Å to 400 Å.

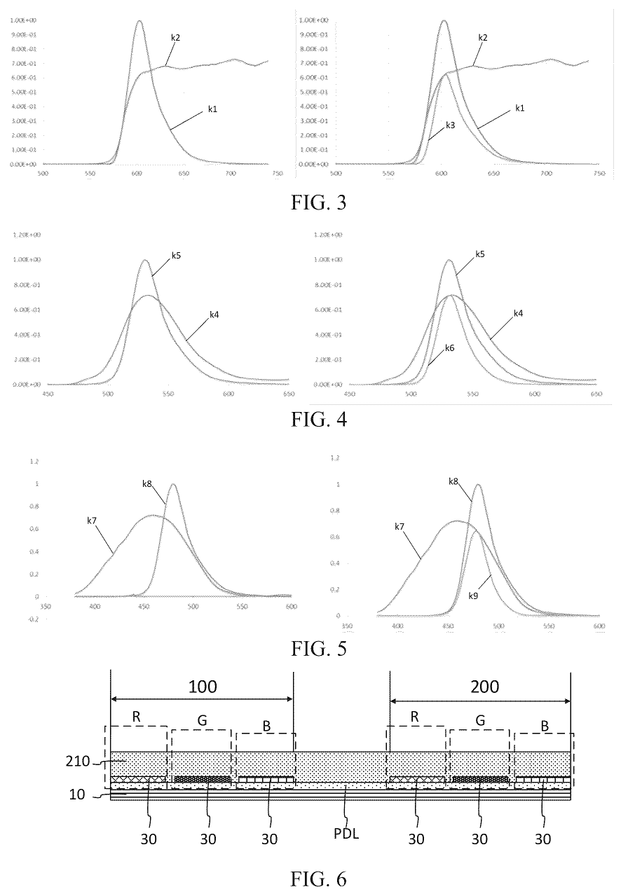

As shown in FIG. 2, in this exemplary embodiment, the length of the microcavity of the R, G, or B sub-pixel in the first display area 100 may be greater than or equal to the length of the microcavity of the corresponding sub-pixel in the second display area 200, and the peak wavelength of the luminescence spectrum curve of each sub-pixel may be determined based on the length of the microcavity of each sub-pixel in the first display area 100. The peak wavelength refers to the wavelength corresponding to the maximum light-emitting intensity of the material, that is, the wavelength at the highest point in the luminescence spectrum curve. For example, FIG. 3 shows luminescence spectrum curves of an R sub-pixel according to an embodiment of the present disclosure, FIG. 4 shows luminescence spectrum curves of a G sub-pixel according to an embodiment of the present disclosure, and FIG. 5 shows luminescence spectrum curves of a B sub-pixel according to an embodiment of the present disclosure. In FIGS. 3-5, the abscissa indicates the wavelength of light, the vertical coordinate indicates the light-emitting intensity, the curve k1 indicates the luminous spectrum curve of the R sub-pixel before filtering, k2 indicates the absorption spectrum curve of red light, k3 indicates the spectrum curve of the emitted light of the R sub-pixel, the curve k4 indicates the luminous spectrum curve of the CG sub-pixel before filtering, k5 indicates the absorption spectral curve of green light, k6 indicates the spectrum curve of the emitted light of the G sub-pixel, and the curve k7 indicates the luminous spectrum curve of the B sub-pixel before filtering, k8 indicates the absorption spectral curve of blue light, and k9 indicates the spectrum curve of the emitted light of the B sub-pixel. It can be seen in the FIGS. 3-5 that the peak wavelength of the luminescence spectrum curve of the R sub-pixel is located in the range of 585-605 nm, the peak wavelength of the luminescence spectrum curve of the G sub-pixel is 530 nm, and the peak wavelength of the luminescence spectrum curve of the B sub-pixel is located in the range of 505-525 nm The peak wavelength of the luminescence spectrum curve of the R sub-pixel is longer than that of the G sub-pixel, which results in a red shift in the spectrum of the light emitted from the organic electroluminescent layer EML in the R sub-pixel, and then the R sub-pixel emits red light through the filtering effect of the color film layer. Similarly, the peak wavelength of the luminescence spectrum curve of the B sub-pixel is smaller than that of the G sub-pixel, which results in a blue shift in the spectrum of the light emitted from the organic electroluminescent layer EML in the B sub-pixel, and then the B sub-pixel emits blue light through the filtering effect of the color film layer.

In addition, in this exemplary embodiment, a value of a Y coordinate in a Commission Internationale de l'éclairage (CIE) color model of the B sub-pixel in the first display area 100 may be reduced to further reduce the difference in picture quality between the first display area 100 and the second display area 200. For example, the value of the Y coordinate in the CIE color model of the B sub-pixel in the first display area 100 may be reduced to a value less than or equal to 0.075 by adjusting the color film layer, which may be, for example, it may be 0.075, 0.070, 0.065, 0.060, 0.055, 0.050, etc.

In this exemplary embodiment, in the first display area 100, the organic electroluminescent layer EML of each sub-pixel is formed by the first light-emitting material that emits green light. Because the first light-emitting material has a high light-emitting efficiency, the light-emitting efficiencies of both the R sub-pixel and the B sub-pixel in the first display area 100 are enhanced. Table 1 shows a comparison of the efficiency of each sub-pixel according to an embodiment of the present disclosure, wherein the “Related art” listed in Table 1 is that the organic electroluminescent layers of the R, G, and B sub-pixels have different light-emitting colors, and the organic electroluminescent layer of the R sub-pixel is formed by the second light-emitting material, the organic electroluminescent layer of the G sub-pixel is formed by the first light-emitting material, and the organic electroluminescent layer of the B sub-pixel is formed by the third light-emitting material.

TABLE 1

| | | R | G | B |
|---|---|---|---|---|
| Related art | Light-emitting | 100% | 100% | 100% |
| Present disclosure | efficiency | 280% | 100% | 300% |
| Related art | Lifetime | 100% | 100% | 100% |
| Present disclosure | | 570% | 100% | 650% |

As can be seen from Table 1, compared to the proportions in the related art, the organic electroluminescent layers of the R, G, and B sub-pixels in this exemplary embodiment are all formed from the first light-emitting material, which is equivalent to replacing the light-emitting material of the organic electroluminescent layers of the R and B sub-pixels with the first light-emitting material with the highest light-emitting efficiency, thereby enabling the lifetime and efficiency of the R and B sub-pixels to be improved, and it is apparent that the integrated light-emitting efficiency and lifetime of the pixel unit composed of the R, G. and B sub-pixels are both improved.

For example, when the first display area 100 has a low resolution (i.e. Pixels Per Inch (PPI)), the transmittance of the light is no longer a major issue affecting the first display area 100. Moreover, because the lifetime of the pixel units is improved, the first display area 100 has no picture quality problem, and therefore, the aperture ratio of the anodes of the sub-pixels can be reduced to further improve the transmittance of the light. According to the results of one of the simulations in the present disclosure, the integrated lifetime of the pixel units can be improved by 220%, and the light-emitting efficiency can be improved by 3%, when the first display area 100 has the low PPI.

When the first display area 100 has a high PPI, as shown in Table 2, in the related art listed in Table 2, the organic electroluminescent layer of the R sub-pixel is formed by the second light-emitting material, the organic electroluminescent layer of the G sub-pixel is formed by the first light-emitting material, and the organic electroluminescent layer of the B sub-pixel is formed by the third light-emitting material, and the PDL GAP denotes the spacing distance of adjacent sub-pixels, and the greater the PDL GAP is, the smaller the aperture ratio of the pixel is and the higher the transmittance of the light is. Compared to the lifetime of the pixel unit in the related art, the lifetime of the first display area 100 in this exemplary embodiment can be significantly improved, and the difference between the lifetime of the first display area 100 and the lifetime of the second display area 200 can be significantly reduced, so that the small difference in the lifetime of the first display area 100 and the second display area 200 can be adjusted by the lifetime compensation algorithm, ultimately enabling the lifetime of the first display area 100 to be the sane as the lifetime of the second display area 200. In this way, the display problem is solved, which is caused by the large difference in picture quality between the first display area 100 and the second display area 200 in the related art due to the low lifetime of the first display area 100.

TABLE 2

| | PDL GAP (μm) | 21 | 22 | 23 | 24 | 25 |
|---|---|---|---|---|---|---|
| First | Lifetime in related art (h) | 194 | 180 | 167 | 152 | 137 |
| display | Lifetime in present disclosure | 430 | 396 | 367 | 334 | 301 |
| area | (h) | | | | | |
| Second | Lifetime (h) | 644 | 548.6 | 467.2 | 391.9 | 327.6 |
| display | | | | | | |
| area | | | | | | |

It is known that the B sub-pixel has the shortest lifetime in a pixel unit, so it is usually necessary to ensure that the B sub-pixel has the largest aperture ratio, the G sub-pixel has the second largest aperture ratio, and the R sub-pixel has the smallest aperture ratio to balance the lifetimes of the three sub-pixels. As shown in Table 1, since the lifetime and efficiency of the R sub-pixel and the B sub-pixel are both improved, the lifetime of the B sub-pixel is no longer a major factor affecting the lifetime and the transmittance of the light of the first display area 100, and the aperture ratio of the B sub-pixel in the first display area 100 can be reduced to correspondingly improve the transmittance of the light of the first display area 100, so that the transmittance of the light of the first display area 100 can be balanced with the service life.

For example, the aperture ratio of the R sub-pixel in the first display area 100 is k1, the aperture ratio of the G sub-pixel is k2, the aperture ratio of the B sub-pixel is k3, wherein k1/k2 may be greater than or equal to 1/2 and less than or equal to 1, and k1/k3 may be greater than or equal to 1/4 and less than or equal to 3/4, e.g., k1/k2 may be equal to 1/2, 3/4, or 1, and k1/k3 may be equal to 1/4, 3/8, 1/2, or, 3/4, etc.

As can be seen, in the case where the first light-emitting material with high light-emitting efficiency is used to form the organic electroluminescent layer EML of the first display area 100, the lifetime and efficiency of the R sub-pixel and the B sub-pixel in the first display area 100 can be improved, so that the aperture ratio of the B sub-pixel can be reduced on the premise of guaranteeing the transmittance of the light of the first display area 100, and/or the aperture ratios of the R sub-pixel and the G sub-pixel can be increased appropriately, so as to realize that while the transmittance of the light of the first display area 100 can be increased, the lifetime of the first display area 100 can still be guaranteed.

In view of the above, in the display panel provided by the present disclosure, the service life and transmittance of the light of the FDC area can be improved, and together with the lifetime compensation algorithm, the service life of the FDC area can be guaranteed to be the same as or close to the service life of the normal display area, thereby solving the problem of poor display of the FDC area.

The present disclosure also provides a method for preparing a display panel, which is used for preparing the display panel described in any of the above embodiments. The method may include the following steps.

S110, providing a substrate 10, where the substrate 10 includes a first display area 100 and a second display area 200. The first display area 100 is configured for image display and light transmission, and the second display area 200 is configured for image display and at least partially surrounds the first display area 100. Each of the first display area 100 and the second display area 200 includes a plurality of sub-pixels emitting light of different colors.

S120, forming a light-emitting functional layer 20 on a side of the substrate 10 by using an evaporation process, where the light-emitting functional layer 20 includes an organic electroluminescent layer EML, organic electroluminescent layers EM L of respective sub-pixels of the plurality of sub-pixels in the first display area 100 emitting light of a same color.

As described in the above embodiments, the first display area 100 may be an FDC area and the second display area may be a normal display area. The plurality of sub-pixels may include, for example, an R sub-pixel emitting red light, a G sub-pixel emitting green light, and a B sub-pixel emitting blue light.

In step S110, a first electrode layer and a pixel definition layer PDL may be formed in the first display area 100 and the second display area 200 on the substrate 10, and the pixel definition layer PDL may be patterned using a patterning process to form a pixel definition structure, with adjacent pixel definition structures defining a sub-pixel. For example, the first electrode layer 30 may include a plurality of first electrodes spaced apart, an orthographic projection of each first electrode on the substrate is located in a pixel area, the first electrode may be an anode, and an organic photoresist material may be coated on the substrate 10 formed with the anode layer, and the method of coating may include slit-type coating, spin-coating, and the like, in which a thickness of the organic photoresist material is higher than a height of the anode layer, and then a semi-etching or ion etching is carried out to the organic photoresist material to remove the organic material layer on the surface of the anode layer to form the pixel definition layer PDL. The patterning process may include an Exposure Developer process. A plurality of pixel definition structures may be formed using the patterning process, the plurality of pixel definition structures 310 being spaced apart in the direction of the extension of the pixel definition layer PDL, with two adjacent pixel definition structures defining a sub-pixel.

Step S120 is to form an organic electroluminescent layer EML by an evaporation process. By evaporating the same light-emitting material in the first display area 100 to form an organic electroluminescent layer EML for each sub-pixel, it can enable the respective sub-pixels in the first display area 100 to have the same turn-on voltage, solve the problem of color cast of the white screen in low gray scale, and improve the display picture quality of the first display area 100.

Further, the organic electroluminescent layer EML of each sub-pixel in the first display area 100 may be formed from a first light-emitting material with the highest light-emitting efficiency, i.e., the organic electroluminescent layer EML of the first display area 100 emits green light, thereby improving the lifetime of each sub-pixel and the transmittance of the light in the first display area 100. The evaporation process of step S120 is further described below with an example of evaporating the first light-emitting material that emits green light in the first display area 100. Step S120 may specifically include the following steps.

S121, forming a first organic layer 210 by evaporating a first organic material on the pixel definition layer PDL and the first electrode layer. The first organic layer 210 may include a hole injection layer HIL and a hole transport layer HTL. The structure of the resulting sub-pixel of a pixel unit of the first display area 100 and the second display area 200 is shown in FIG. 6.

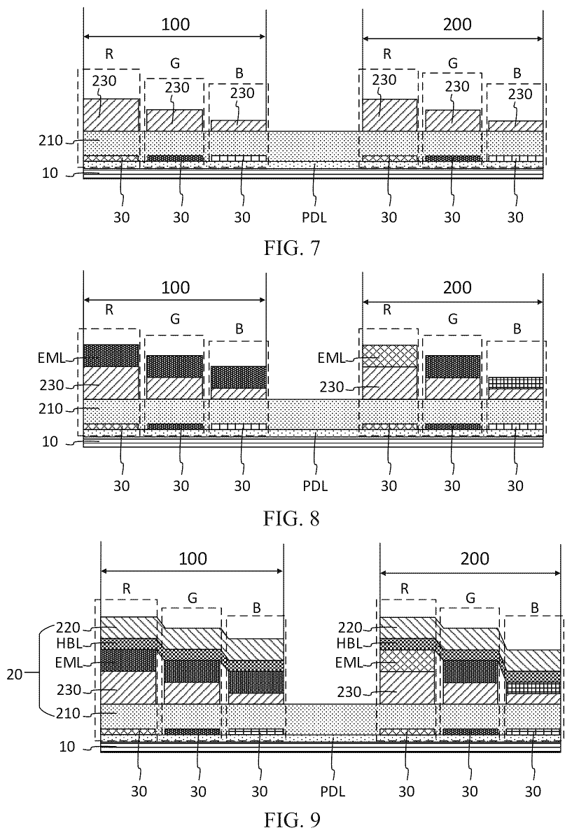

S122, forming an array of an R light-emitting adjustment layer 230, a G light-emitting adjustment layer 230 and a B light-emitting adjustment layer 230 by evaporation on the first organic layer 210. The thicknesses of the R light-emitting adjustment layer 230, the G light-emitting adjustment layer 230, and the B light-emitting adjustment layer 230 are different from each other, with the thickness of the light-emitting adjustment layer 230 of the B sub-pixel being the smallest and the thickness of the light-emitting adjustment layer 230 of the R sub-pixel being the largest, and the light-emitting adjustment layers 230 of different thicknesses can be formed by evaporation on the first organic layer 210 using a Fine Metal Plate (FMM), so as to obtain the structure of the pixel unit as shown in FIG. 7.

S123, forming the organic electroluminescent layer EML of the second display area 200 by evaporating a second light-emitting material on the R light-emitting adjustment layer 230 of the second display area 200, a first light-emitting material on the G light-emitting adjustment layer 230 of the second display area 200, and a third light-emitting material on the B light-emitting adjustment layer 230 of the second display area 200, respectively, and forming the organic electroluminescent layer EML, of the first display area 100 by evaporating the first light-emitting material on the R light-emitting adjustment layer, the G light-emitting adjustment layer, and the B light-emitting adjustment layer of the first display area 100.

In this step, the second light-emitting material can be evaporated in the R sub-pixel of the second display area 200, the first light-emitting material can be evaporated in the G sub-pixels of the second display area 200 and the first display area 100, and the third light-emitting material can be evaporated in the B sub-pixel of the second display area 200, respectively, using a fine metal mask. That is, the second light-emitting material and the third light-emitting material are not evaporated in the first display area 100, and only the first light-emitting material is evaporated, so that the organic electroluminescent layers EML of the R, G, and B sub-pixels of the first display area 100 emit light of the same color and have the highest light-emitting efficiency, thereby extending the lifetime of the R sub-pixel and the B sub-pixel. The structure of the resulting pixel unit is shown in FIG. 8.

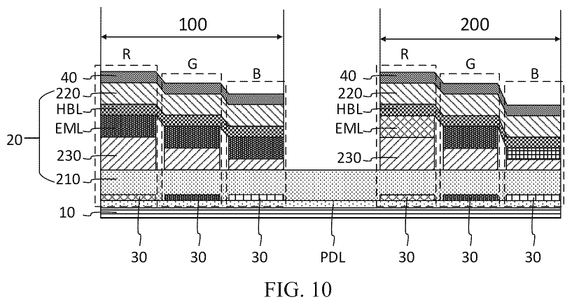

S124, forming a second organic layer 220 by evaporating a second organic material on the organic electroluminescent layer EML. The second organic layer 220 may include an electron transport layer ETL and an electron injection layer EIL. In some embodiments, a hole blocking layer HBL may be evaporated on the organic electroluminescent layer EML, and the second organic layer 220 may be formed by evaporation the hole blocking layer HBL. The structure of the resulting pixel unit is shown in FIG. 9.

After forming the light-emitting functional layer 20 by evaporation, a second electrode layer 220 can be further evaporated on the light-emitting functional layer to obtain a structure of a pixel unit as shown in FIG. 10.

Further, a color film layer may be formed on the second electrode layer 220 using an encapsulation process, the color film layer including filter portions corresponding to respective sub-pixels, the filter portion being configured for transmitting light of a corresponding color.

In addition, the present disclosure also provides a display device which may include the display panel as described in any of the above embodiments of the present disclosure, and thus the display device also has the beneficial effects described in any of the above embodiments.

According to a first aspect of the present disclosure, there is provided a display panel, including: a substrate including a first display area and a second display area at least partially surrounding the first display area, the first display area being configured for image display and light transmission, the second display area being configured for image display.; and a light-emitting functional layer on a side of the substrate, including an organic electroluminescent layer; wherein each of the first display area and the second display area includes a plurality of sub-pixels emitting light of different colors, and organic electroluminescent layers of respective sub-pixels of the plurality of sub-pixels in the first display area emit light of a same color.

In exemplary embodiments of the present disclosure, the plurality of sub-pixels in the first display area include at least a first sub-pixel and a second sub-pixel, a color of light emitted from the first sub-pixel being different from a color of light emitted from the second sub-pixel; and the organic electroluminescent layer of the first sub-pixel and the organic electroluminescent layer of the second sub-pixel are formed by a first light-emitting material, wherein a light-emitting color of the first light-emitting material is the same as the color of the light emitted from the first sub-pixel, a light-emitting efficiency of the first light-emitting material is greater than a light-emitting efficiency of a second light-emitting material, and a light-emitting color of the second light-emitting material is the same as the color of the light emitted from the second sub-pixel.

In exemplary embodiments of the present disclosure, the plurality of sub-pixels in the first display area include an R sub-pixel emitting red light, a G sub-pixel emitting green light, and a B sub-pixel emitting blue light; and the organic electroluminescent layers of the respective sub-pixels of the plurality of sub-pixels in the first display area emit green light.

In exemplary embodiments of the present disclosure in the first display area, a thickness of the organic electroluminescent layer of the R sub-pixel, a thickness of the organic electroluminescent layer of the G sub-pixel, and a thickness of the organic electroluminescent layer of the B sub-pixel decrease in sequence.

In exemplary embodiments of the present disclosure, the organic electroluminescent layers of the respective sub-pixels of the plurality of sub-pixels in the first display area have a same thickness.

In exemplary embodiments of the present disclosure, the light-emitting functional layer further includes: a first organic layer between the organic electroluminescent layer and the substrate; and a light-emitting adjustment layer between the organic electroluminescent layer and the first organic layer; wherein, in the first display area, the thickness of the organic electroluminescent layers of the respective sub-pixels of the plurality of sub-pixels is d1, and a thickness of the light-emitting adjustment layer of the B sub-pixel is d2, d1/d2 being greater than or equal to 3 and less than or equal to 9.

In exemplary embodiments of the present disclosure, a pixel resolution of the first display area is the same as a pixel resolution of the second display area.

In exemplary embodiments of the present disclosure, in the first display area, an aperture ratio of the R sub-pixel is k1, an aperture ratio of the G sub-pixel is k2, and an aperture ratio of the B sub-pixel is k3, k1/k2 being greater than or equal to 1/2 and less than or equal to 1, k1/k3 being greater than or equal to 1/4 and less than or equal to 3/4.

In exemplary embodiments of the present disclosure, the light-emitting functional layer further includes: a first organic layer between the organic electroluminescent layer and the substrate; a light-emitting adjustment layer between the organic electroluminescent layer and the first organic layer; and a second organic layer on a side of the organic electroluminescent layer away from the substrate, covering the organic electroluminescent layer; and the display panel further includes: a first electrode layer between the substrate and the first organic layer; and a second electrode layer on a side of the second organic layer away from the substrate, covering the second organic layer; wherein the stacked first electrode layer, the first organic layer, the light-emitting adjustment layer, the organic electroluminescent layer, the second organic layer, and the second electrode layer form a microcavity of the sub-pixel, with a length of the microcavity of the R sub-pixel, a length of the microcavity of the G sub-pixel, and a length of the microcavity of the B sub-pixel decreasing in sequence in the first display area.

In exemplary embodiments of the present disclosure, the length of the microcavity of the R sub-pixel in the first display area, is greater than a length of a microcavity of a R sub-pixel in the second display area; the length of the microcavity of the G sub-pixel in the first display area, is equal to a length of a microcavity of a B sub-pixel in the second display area; and the length of the microcavity of the B sub-pixel in the first display area, is greater than a length of a microcavity of the B sub-pixel in the second display area

In exemplary embodiments of the present disclosure, in the first display area, the length of the microcavity of the R sub-pixel is greater than or equal to 2700 nm and less than or equal to 2900 nm, and the length of the microcavity of the B sub-pixel is greater than or equal to 1900 nm and less than or equal to 2100 nm.

In exemplary embodiments of the present disclosure, in the first display area, a peak wavelength of a luminescence spectrum curve of the R sub-pixel ranges from 585 nm to 605 nm, and a peak wavelength of a luminescence spectrum curve of the B sub-pixel ranges from 505 nm to 525 nm.

In exemplary embodiments of the present disclosure, in the first display area, a value of a Y coordinate in a Commission Interationale de l'éclairage (CIE) color model of the B sub-pixel is less than or equal to 0.075.

According to a second aspect of the present disclosure, there is provided a method for preparing a display panel, wherein the method is configured for preparing the display panel of any one of the embodiments of the present disclosure. The method includes: providing a substrate, wherein the substrate includes: a first display area configured for image display and light transmission, and a second display area at least partially surrounding the first display area, configured for image display, each of the first display area and the second display area including a plurality of sub-pixels emitting light of different colors; and forming a light-emitting functional layer on a side of the substrate by using an evaporation process, wherein the light-emitting functional layer includes an organic electroluminescent layer, organic electroluminescent layers of respective sub-pixels of the plurality of sub-pixels in the first display area emitting light of a same color.

In exemplary embodiments of the present disclosure, forming the light-emitting functional layer on the side of the substrate by the evaporation process, includes: forming a first organic layer by evaporation on the first display area and the second display area on the substrate; forming an array of an R light-emitting adjustment layer, a G light-emitting adjustment layer and a B light-emitting adjustment layer by evaporation on the first organic layer; forming the organic electroluminescent layer of the second display area by evaporating a second light-emitting material on the R light-emitting adjustment layer of the second display area, a first light-emitting material on the G light-emitting adjustment layer of the second display area, and a third light-emitting material on the B light-emitting adjustment layer of the second display area, respectively, and forming the organic electroluminescent layer of the first display area by evaporating the first light-emitting material on the R light-emitting adjustment layer, the G light-emitting adjustment layer, and the B light-emitting adjustment layer of the first display area, wherein a light-emitting efficiency of the first light-emitting material is greater than a light-emitting efficiency of the second light-emitting material, and the light-emitting efficiency of the first light-emitting material is greater than a light-emitting efficiency of the third light-emitting material; and forming a second organic layer by evaporation on the org electroluminescent layer.

In exemplary embodiments of the present disclosure, before forming the light-emitting functional layer on the side of the substrate by the evaporation process, the method further includes: forming a first electrode layer and a pixel definition layer in the first display area and the second display area on the substrate; and forming a pixel definition structure by patterning the pixel definition layer using a patterning process, wherein adjacent pixel definition structures define a sub-pixel of the plurality of sub-pixels.

In exemplary embodiments of the present disclosure, after forming the light-emitting functional layer on the side of the substrate by the evaporation process, the method further includes: forming a second electrode layer by evaporation on the light-emitting functional layer; and forming a color film layer on the second electrode layer using an encapsulation process, wherein the color film layer includes filter portions corresponding to the respective sub-pixels of the plurality of sub-pixels, the filter portion is configured for transmitting light of a corresponding color.

According to a third aspect of the present disclosure, there is provided a display device, including the display panel as described in any one of embodiments of the present disclosure.

In the display panel provided by the present disclosure, both the first display area and the second display area include sub-pixels emitting light of different colors, and the light emitted from the organic electroluminescent layers of the respective sub-pixels in the first display area has the same color. That is, the organic electroluminescent layers of the respective sub-pixels in the first display area are formed by the same material, thereby enabling the respective sub-pixels in the first display area to have the same turn-on voltage and solving the problem of color cast of the white screen in low gray scale.

Other embodiments of the disclosure will be readily apparent to those skilled in the art from consideration of the specification and practice of the invention disclosed herein. The present disclosure is intended to cover any variations, uses, or adaptations of the disclosure that follow the general principles of the disclosure and include common knowledge or customary means in the field of the art that are not disclosed herein. The specification and embodiments are to be regarded as exemplary only, and the true scope and spirit of the present disclosure is indicated by the appended claims.

1. A display panel, comprising:
a substrate comprising a first display area and a second display area at least partially surrounding the first display area, the first display area being configured for image display and light transmission, the second display area being configured for image display; and
a light-emitting functional layer on a side of the substrate, comprising an organic electroluminescent layer;
wherein each of the first display area and the second display area comprises a plurality of sub-pixels emitting light of different colors, and organic electroluminescent layers of respective sub-pixels of the plurality of sub-pixels in the first display area emit light of a same color.

2. The display panel of claim 1, wherein the plurality of sub-pixels in the first display area comprise at least a first sub-pixel and a second sub-pixel, a color of light emitted from the first sub-pixel being different from a color of light emitted from the second sub-pixel; and
the organic electroluminescent layer of the first sub-pixel and the organic electroluminescent layer of the second sub-pixel are formed by a first light-emitting material, wherein a light-emitting color of the first light-emitting material is the same as the color of the light emitted from the first sub-pixel, a light-emitting efficiency of the first light-emitting material is greater than a light-emitting efficiency of a second light-emitting material, and a light-emitting color of the second light-emitting material is the same as the color of the light emitted from the second sub-pixel.

3. The display panel of claim 2, wherein the plurality of sub-pixels in the first display area comprise an R sub-pixel emitting red light, a G sub-pixel emitting green light, and a B sub-pixel emitting blue light; and
the organic electroluminescent layers of the respective sub-pixels of the plurality of sub-pixels in the first display area emit green light.

4. The display panel of claim 3, wherein, in the first display area, a thickness of the organic electroluminescent layer of the R sub-pixel, a thickness of the organic electroluminescent layer of the G sub-pixel, and a thickness of the organic electroluminescent layer of the B sub-pixel decrease in sequence.

5. The display panel of claim 3, wherein the organic electroluminescent layers of the respective sub-pixels of the plurality of sub-pixels in the first display area have a same thickness.

6. The display panel of claim 5, wherein the light-emitting functional layer further comprises:
a first organic layer between the organic electroluminescent layer and the substrate; and
a light-emitting adjustment layer between the organic electroluminescent layer and the first organic layer;
wherein, in the first display area, the thickness of the organic electroluminescent layers of the respective sub-pixels of the plurality of sub-pixels is d1, and a thickness of the light-emitting adjustment layer of the B sub-pixel is d2, d1/d2 being greater than or equal to 3 and less than or equal to 9.

7. The display panel of claim 3, wherein a pixel resolution of the first display area is the same as a pixel resolution of the second display area.

8. The display panel of claim 7, wherein, in the first display area, an aperture ratio of the R sub-pixel is k1, an aperture ratio of the G sub-pixel is k2, and an aperture ratio of the B sub-pixel is k3, k1/k2 being greater than or equal to 1/2 and less than or equal to 1, k1/k3 being greater than or equal to 1/4 and less than or equal to 3/4.

9. The display panel of claim 3, wherein the light-emitting functional layer further comprises:
a first organic layer between the organic electroluminescent layer and the substrate;
a light-emitting adjustment layer between the organic electroluminescent layer and the first organic layer; and
a second organic layer on a side of the organic electroluminescent layer away from the substrate, covering the organic electroluminescent layer; and
wherein the display panel further comprises:
a first electrode layer between the substrate and the first organic layer; and
a second electrode layer on a side of the second organic layer away from the substrate, covering the second organic layer;
wherein the stacked first electrode layer, the first organic layer, the light-emitting adjustment layer, the organic electroluminescent layer, the second organic layer, and the second electrode layer form a microcavity of the sub-pixel, with a length of the microcavity of the R sub-pixel, a length of the microcavity of the G sub-pixel, and a length of the microcavity of the B sub-pixel decreasing in sequence in the first display area.

10. The display panel of claim 9, wherein
the length of the microcavity of the R sub-pixel in the first display area, is greater than a length of a microcavity of a R sub-pixel in the second display area;
the length of the microcavity of the G sub-pixel in the first display area, is equal to a length of a microcavity of a B sub-pixel in the second display area; and
the length of the microcavity of the B sub-pixel in the first display area, is greater than a length of a microcavity of the B sub-pixel in the second display area.

11. The display panel of claim 10, wherein, in the first display area, the length of the microcavity of the R sub-pixel is greater than or equal to 2700 nm and less than or equal to 2900 nm, and
the length of the microcavity of the B sub-pixel is greater than or equal to 1900 nm and less than or equal to 2100 nm.

12. The display panel of claim 3, wherein, in the first display area, a peak wavelength of a luminescence spectrum curve of the R sub-pixel ranges from 585 nm to 605 nm, and
a peak wavelength of a luminescence spectrum curve of the B sub-pixel ranges from 505 nm to 525 nm.

13. The display panel of claim 3, wherein, in the first display area, a value of a Y coordinate in a Commission Internationale de l'eclairage (CIE) color model of the B sub-pixel is less than or equal to 0.075.

14. A method for preparing a display panel, wherein the method is configured for preparing the display panel of claim 1, the method comprising:
providing a substrate, wherein the substrate comprises:
a first display area configured for image display and light transmission, and
a second display area at least partially surrounding the first display area, configured for image display, each of the first display area and the second display area comprising a plurality of sub-pixels emitting light of different colors; and
forming a light-emitting functional layer on a side of the substrate by using an evaporation process, wherein the light-emitting functional layer comprises an organic electroluminescent layer, organic electroluminescent layers of respective sub-pixels of the plurality of sub-pixels in the first display area emitting light of a same color.

15. The method of claim 14, wherein forming the light-emitting functional layer on the side of the substrate by the evaporation process, comprises:
forming a first organic layer by evaporation on the first display area and the second display area on the substrate;
forming an array of an R light-emitting adjustment layer, a G light-emitting adjustment layer and a B light-emitting adjustment layer by evaporation on the first organic layer;
forming the organic electroluminescent layer of the second display area by evaporating a second light-emitting material on the R light-emitting adjustment layer of the second display area, a first light-emitting material on the G light-emitting adjustment layer of the second display area, and a third light-emitting material on the B light-emitting adjustment layer of the second display area, respectively, and forming the organic electroluminescent layer of the first display area by evaporating the first light-emitting material on the R light-emitting adjustment layer, the G light-emitting adjustment layer, and the B light-emitting adjustment layer of the first display area, wherein a light-emitting efficiency of the first light-emitting material is greater than a light-emitting efficiency of the second light-emitting material, and the light-emitting efficiency of the first light-emitting material is greater than a light-emitting efficiency of the third light-emitting material; and
forming a second organic layer by evaporation on the organic electroluminescent layer.

16. The method of claim 14, wherein, before forming the light-emitting functional layer on the side of the substrate by the evaporation process, the method further comprises:
forming a first electrode layer and a pixel definition layer in the first display area and the second display area on the substrate; and
forming a pixel definition structure by patterning the pixel definition layer using a patterning process, wherein adjacent pixel definition structures define a sub-pixel of the plurality of sub-pixels.

17. The method of claim 14, wherein, after forming the light-emitting functional layer on the side of the substrate by the evaporation process, the method further comprises:
forming a second electrode layer by evaporation on the light-emitting functional layer; and
forming a color film layer on the second electrode layer using an encapsulation process, wherein the color film layer comprises filter portions corresponding to the respective sub-pixels of the plurality of sub-pixels, the filter portion is configured for transmitting light of a corresponding color.

18. A display device, comprising a display panel, wherein the display panel comprises:
a substrate comprising a first display area and a second display area at least partially surrounding the first display area, the first display area being configured for image display and light transmission, the second display area being configured for image display; and
a light-emitting functional layer on a side of the substrate, comprising an organic electroluminescent layer;
wherein each of the first display area and the second display area comprises a plurality of sub-pixels emitting light of different colors, and organic electroluminescent layers of respective sub-pixels of the plurality of sub-pixels in the first display area emit light of a same color.

19. The display device of claim 18, the plurality of sub-pixels in the first display area comprise at least a first sub-pixel and a second sub-pixel, a color of light emitted from the first sub-pixel being different from a color of light emitted from the second sub-pixel; and
the organic electroluminescent layer of the first sub-pixel and the organic electroluminescent layer of the second sub-pixel are formed by a first light-emitting material, wherein a light-emitting color of the first light-emitting material is the same as the color of the light emitted from the first sub-pixel, a light-emitting efficiency of the first light-emitting material is greater than a light-emitting efficiency of a second light-emitting material, and a light-emitting color of the second light-emitting material is the same as the color of the light emitted from the second sub-pixel.

20. The display device of claim 19, wherein the plurality of sub-pixels in the first display area comprise an R sub-pixel emitting red light, a G sub-pixel emitting green light, and a B sub-pixel emitting blue light; and
the organic electroluminescent layers of the respective sub-pixels of the plurality of sub-pixels in the first display area emit green light.
